(19) United States
(12) Patent Application Publication
(10) Pub. No.: US 2013/0341635 A1
(43) Pub. Date: Dec. 26, 2013

(54) DOUBLE ALUMINUM NITRIDE SPACERS FOR NITRIDE HIGH ELECTRON-MOBILITY TRANSISTORS

(71) Applicant: IQE, KC, LLC, Taunton, MA (US)

(72) Inventors: Yu Cao, Norwood, MA (US); Oleg Laboutin, South Easton, MA (US); Wayne Johnson, Easton, MA (US)

(21) Appl. No.: 13/912,899

(22) Filed: Jun. 7, 2013

Related U.S. Application Data
(60) Provisional application No. 61/656,875, filed on Jun. 7, 2012.

(51) Int. Cl. H01L 29/778; H01L 29/66

(52) U.S. Cl. CPC H01L 29/7783; H01L 29/66462
USPC 257/76; 438/172

(57) ABSTRACT

An epitaxial structure and a high electron mobility transistor (HEMT) employing the epitaxial structure includes a first spacer layer over a channel layer, a first barrier layer over the first spacer layer, and a second spacer layer over the first barrier layer.

### RELATED APPLICATION

This application claims the benefit of U.S. Provisional Application No. 61/656,875, filed on Jun. 7, 2012. The entire teachings of the above application are incorporated herein by reference.

### BACKGROUND OF THE INVENTION

Optimization of gallium nitride (GaN) high electron mobility transistors (HEMTs) for high frequency applications involves complex tradeoffs between the epitaxial layer design and the device fabrication and layout. The thickness of the barrier layer component of the HEMT structure can be a limiting factor because, as thickness of the barrier layer decreases, HEMT gate leakage can become a significant factor affecting performance, especially in radio frequency (RF) applications. A thin barrier can lead to electrons tunneling through the barrier layer, thereby reducing reliability or rendering the transistor inoperable altogether. Reducing gate leakage also helps improve device performance, as measured by parametrics such as on/off ratio, maximum operating frequencies, and power consumption.

One option to decrease electron tunneling in GaN-based HEMTs is to increase the effective barrier height by introducing a spacer layer of aluminum nitride between a gallium nitride channel layer of the HEMT and an indium aluminum gallium (InAlGaN) nitride barrier layer. Such a spacer layer causes a positive conduction band offset between the aluminum nitride of the spacer layer material and barrier layer materials, typically comprised of aluminum gallium nitride (AlGaN), indium aluminum nitride (InAlN), or indium aluminum gallium nitride (InAlGaN). However, the effectiveness of an aluminum nitride spacer layer between a channel layer and the barrier layer of a HEMT structure is limited and there is a need for a HEMT structure that can help minimize or eliminate the problems of gate leakage in devices employing thin barrier layers.

### SUMMARY OF THE INVENTION

The invention generally is directed to an epitaxial structure that includes a first spacer layer between a channel layer and a first barrier layer, and a second spacer layer between the first barrier layer and a second barrier layer, and to a method of forming such an epitaxial structure.

In one embodiment, the invention is an epitaxial structure that includes a substrate and a buffer layer on the substrate. A channel layer is over the buffer layer and includes a 2-dimensional electron gas region distal to the buffer layer. The first spacer layer is over the channel layer and a first barrier layer is over the first spacer layer. A second spacer layer is over the first barrier layer. In one embodiment, a second barrier layer is over the second spacer layer.

In another embodiment, the invention is a method of forming a epitaxial structure that includes the steps of forming a substrate, forming a buffer layer on the substrate and forming a channel layer over the buffer layer. The first spacer layer is formed over the channel layer, a second barrier layer is formed on the first spacer layer, while a second spacer layer is formed on the first barrier layer, whereby a 2-dimensional electron gas region is formed in the channel layer distal to the buffer layer as a result of forming the first and second barrier layers. In one embodiment, a second barrier layer is formed over the second spacer layer.

This invention has many advantages. For example, the inventors have discovered that, unexpectedly, the inclusion of a second spacer layer, interposed between two barrier layers, significantly decreases the likelihood and effect of electrons tunneling through the barrier layer in a HEMT structure relative to an epitaxial structure having the same overall thickness of combined spacer and barrier layers, but employing only a single spacer layer between the channel layer and the barrier layer. Although not wishing to be limited to any particular theory, it is believed that the effective barrier height for electrons is increased by employing a second spacer layer interposed within a barrier layer, but without significant deleterious effect on the performance of the HEMT structures relative to HEMT structures having the same combined thickness of spacer and barrier layers.

### BRIEF DESCRIPTION OF THE DRAWINGS

FIG. 1 is a schematic representation of an epitaxial structure of the prior art, showing an aluminum nitride spacer layer between a gallium nitride channel layer and an aluminum nitride barrier layer.

FIG. 2 is a schematic representation of an epitaxial structure of the invention, showing a second aluminum nitride spacer layer partitioning upper and lower barrier layers.

FIG. 3 is a simulated plot showing the effective barrier heights of an indium aluminum nitride barrier layer in the epitaxial structure of a prior art HEMT structure, such as is represented in FIG. 1.

FIG. 4 shows a simulated plot of the effective barrier heights of an indium aluminum nitride barrier layer where two aluminum nitride spacers are employed, as in the embodiment of the invention schematically represented in FIG. 2.

FIG. 5 is a simulated plot of 2-dimensional gas density (2DEG) versus separation between aluminum nitride spacers for an HEMT structure of the prior art and two embodiments of HEMT structures of the invention.

FIG. 6 is a plot of sheet resistance measured by a contactless sheet resistance probe system versus separation between the aluminum nitride spacers and for two HEMT structures of the prior art and two HEMT structures of the invention.

FIG. 7 is the channel current plotted as a function of gate bias from the FETs on the control sample and the other two samples with double AlN spacers. The drain bias was fixed at 6V. The source is grounded. The gate bias swept from −6V to +2V. The leakage current in the OFF state is more than 2 orders of magnitude lower than that in the control sample.

FIG. 8 is the gate leakage current plotted as a function of gate bias from the FETs on the control sample and the other two samples with double AlN spacers. The drain bias was fixed at 6V. The source is grounded. The gate bias swept from −6V to +2V. The gate leakage current in the OFF state is 1-2 orders of magnitude lower than that in the control sample.

### DETAILED DESCRIPTION OF THE INVENTION

A description of example embodiments of the invention follows.

The teachings of all patents, published applications and references cited herein are incorporated by reference in their entirety.

The invention generally is directed to an epitaxial structure and to a method of forming an epitaxial structure having first and second spacer layers, wherein the second spacer layer is interposed between the first and second barrier layers of the epitaxial structure.

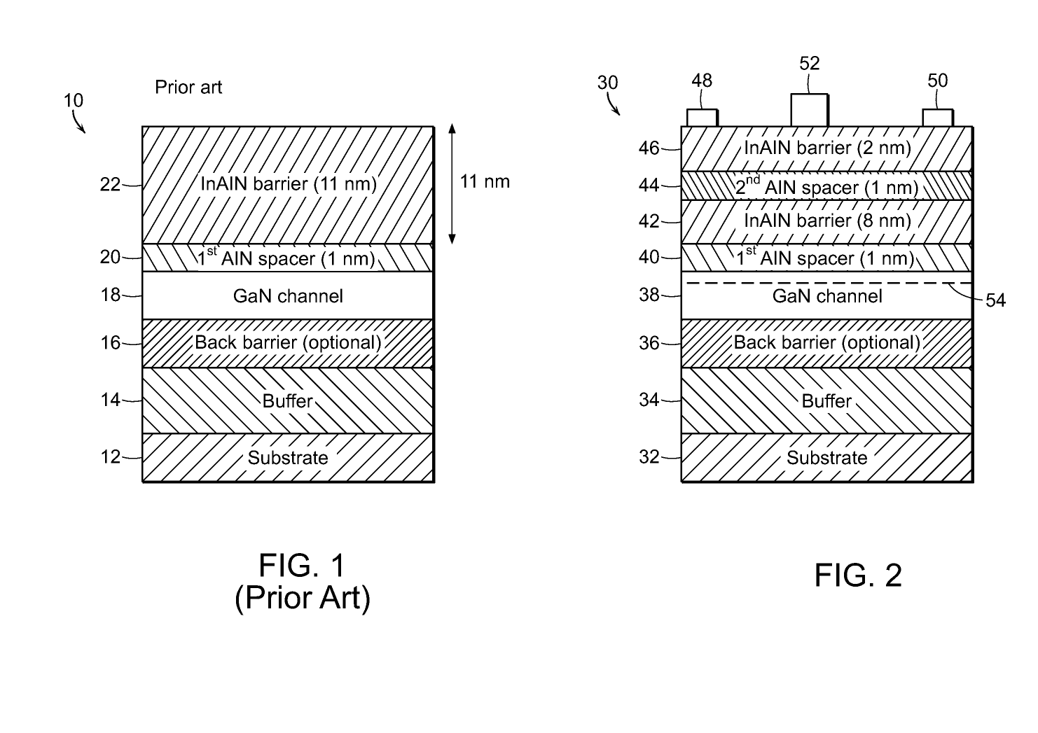

In one embodiment of an epitaxial structure 10 of the prior art, shown in FIG. 1, the epitaxial structure includes substrate 12, buffer layer 14 over substrate 12, and optionally, back barrier layer 16 over buffer layer 14. Channel layer 18, formed of a suitable material, such as gallium nitride (GaN), is disposed over back barrier layer 16. Spacer layer 20, having a typical thickness of about 1 nm, overlays channel layer 18. Indium aluminum nitride (InAlN) barrier layer 22, typically having a thickness of about 11 nm, overlays spacer layer 20. When a layer is referred to as being “on” or “over” another layer or substrate, it can be directly on the layer or substrate, or an intervening layer also may be present.

As understood by those of skill in the art, an epitaxial structure can contain many distinct layers that are, either collectively or individually, designed to achieve desired device characteristics. An epitaxial structure is typically formed over a substrate. Examples of substrate materials for GaN-based epitaxial structures include sapphire (Al2O3), silicon carbide (SiC), silicon (Si), gallium nitride (GaN), or aluminum nitride (AlN). For a GaN-based FET, such as a HEMT, a buffer layer with high electrical resistivity is typically formed over the substrate. For HEMT epitaxial structures, a channel layer is typically formed over the buffer layer and a barrier layer is typically formed over the channel layer. The barrier layer should be formed from a material with larger bandgap than the material used to form the channel layer. When the barrier layer and channel layer are formed using appropriate materials and methods, a large electron concentration can be developed in the channel layer adjacent to the barrier layer. The electrons in this region exhibit high mobility and this collective group of electrons is referred to as a 2-dimensional electron gas (2DEG). It should be noted that certain optional layers may be present or absent in a HEMT epitaxial structure depending on its design. Of particular note, a channel layer may not be employed and, if a large bandgap barrier layer is formed over a buffer layer with smaller bandgap, a 2DEG can be formed in the region of the buffer layer adjacent to the barrier layer. There may also be intervening layers between the channel layer and the barrier layer. A common example is a spacer layer formed directly on the channel layer and between the channel layer and barrier layer. Such a spacer layer can be used to enhance properties of the 2DEG such as electron mobility and electron concentration. For GaN-based HEMTs, a common structure employs a GaN buffer layer, GaN channel layer, AlN spacer layer, and AlGaN barrier layer, although many permutations are possible. Suitable material properties (e.g., bandgap) for the respective layers of GaN-based epitaxial structures are known in the art.

A layer that is “directly on” another layer or substrate means that no intervening layer is present. It should also be understood that when a layer is referred to as being “on” or “over” another layer or substrate, it may cover the entire layer or substrate, or a portion of the layer or substrate.

One embodiment of an epitaxial structure of the invention, suitable for use as a high electron mobility transistor (HEMT) device is shown in FIG. 2. As represented substantially therein, epitaxial structure 30 includes substrate 32 and buffer layer 34 overlaying substrate. Examples of suitable materials of substrate include silicon carbide (SiC), sapphire (Al₂O₃) and silicon (Si). Typically, buffer layer 34 includes at least one material selected from the group consisting of gallium nitride (GaN), indium gallium nitride (InGaN), aluminium gallium nitride (AlGaN). The average thickness of buffer layer 34 typically is in a range of between about 0.1 μm and about 10 μm. Optional back barrier layer 36 overlays buffer layer. Typically, the average thickness of back barrier layer is in a range of between about 10 nm and about 1000 nm. Channel layer 38, formed of a suitable material, such as gallium nitride (GaN), overlays optional back barrier layer. In one embodiment, channel layer 38 consists essentially of InₓGa₁₋ₓN, where 0≦x≦1. Typically, the average thickness of channel layer 38 is in a range of between about 10 nm and about 500 nm. In one embodiment, the average thickness of channel layer 38 is about 100 nm.

First spacer layer 40 overlays channel layer 38. Examples of suitable materials of first spacer layer 40 includes aluminum nitride (AlN), aluminum gallium nitride (AlGaN). Preferably, first spacer layer 40 includes aluminum nitride (AlN). In one embodiment, first spacer layer 40 has an average thickness in the range of between about 0.5 and about 1 nm. In a preferred embodiment, first spacer layer has an average thickness in the range between about 0.5 and about 1 nm. In a particularly preferred embodiment, aluminum nitride spacer layer has a thickness of about 1 nm.

First barrier layer 42 overlays first spacer layer 40. Examples of suitable materials of first barrier layer 42 include aluminum nitride (AlN), aluminum gallium nitride (AlGaN), Indium aluminum nitride (InAlN). The average thickness of the first barrier layer 42 typically is in a range of between about 1 and about 30. Preferably, the average thickness of first barrier layer 42 is in a range of between about 2 and about 10. In one particular embodiment, the average thickness of the first barrier layer 42 is about 2 and 6 nm.

Second aluminum nitride spacer layer 44 overlays first barrier layer 42. Examples of suitable materials of second spacer layer 44 are the same as those of first spacer layer 40. First 40 and second 44 spacer layers can be formed of the same or different materials. The average thickness of second spacer layer 44 typically is a range of between about 0.5 and about 1 nanometers (nm). In a preferred embodiment, the range of average thickness is between about 0.5 and about 1. In the particular preferred embodiment, the average thickness of the second spacer layer 44 is about 1 nm.

Second barrier layer 46 overlays second spacer layer 44. Examples of suitable materials of second barrier layer 46, and suitable average thickness ranges of second barrier layer 46 are the same as those of first barrier layer 42. Second barrier layer 46 is optional.

Typically the combined thickness of first barrier layer 42, second spacer layer 44 and second barrier layer 46 is in a range between about 5 and about 30. Preferably, the average thickness of first barrier layer 42 is about 8 nm, the average thickness of second spacer layer 44 is about 1 nm, and the average thickness of second barrier layer 46 is about 2 nm. In another embodiment, the combined thickness of first barrier layer 42, second spacer layer 44 and second barrier layer 46 is in a range between about 0.5 nm and about 20 nm. In a particularly preferred embodiment, the combined thickness of the first barrier layer 42, second spacer layer 44 and second barrier layer 46 is about 11 nm.

Doping and doping levels suitable for the various layers of the epitaxial structure of the invention are those typically known to those of skill in the art.

In one embodiment, the invention is a high electron mobility transistor (HEMT) structure of the invention. In one embodiment of an HEMT of the invention, shown in FIG. 2, source terminal 48 is in electrical communication with second barrier layer 46 and a drain terminal 50 is in electrical communication with at least one of first barrier layer 42 and second barrier layer 46. Further, gate 52 is in direct electrical communication with at least one of first barrier layer 42 and second barrier layer 46, and is located between source terminal 48 and drain terminal 50, as shown in FIG. 2.

In another embodiment, the invention is a method of forming an epitaxial structure that includes the steps of forming substrate 32, forming buffer layer 34 on substrate 32, optionally forming back barrier layer 36 over buffer layer 34, forming channel layer 38 over buffer layer 34 or optional back barrier layer 36, forming first spacer layer 40 on channel layer 38, forming first barrier layer 42 on first spacer layer 40, forming second barrier layer 44 on first spacer layer 40, and forming second barrier layer 46 on second spacer layer 44, whereby 2-dimensional electron gas 54 is formed in channel layer 38 distal to buffer layer 43 as a result of forming first 42 and second 46 barrier layers. Suitable methods of forming the various layers of epitaxial structure 30 of the invention are known to those of skill in the art.

In another embodiment the invention is a method of forming a high electron mobility transistor (HEMT) structure employing the epitaxial structure of the invention. The method includes, in addition to epitaxial structure 30, forming source 48 and drain 50 terminals in electrical communication with second barrier layer 46, and gate terminal 52 that is in direct electrical communication with at least one of first barrier layer 42 and second barrier layer 46, and between source terminal 48 and drain terminal 50.

The following are non-limiting examples of embodiments of the invention.

### Exemplification

### EXAMPLE 1 (PROPHETIC)

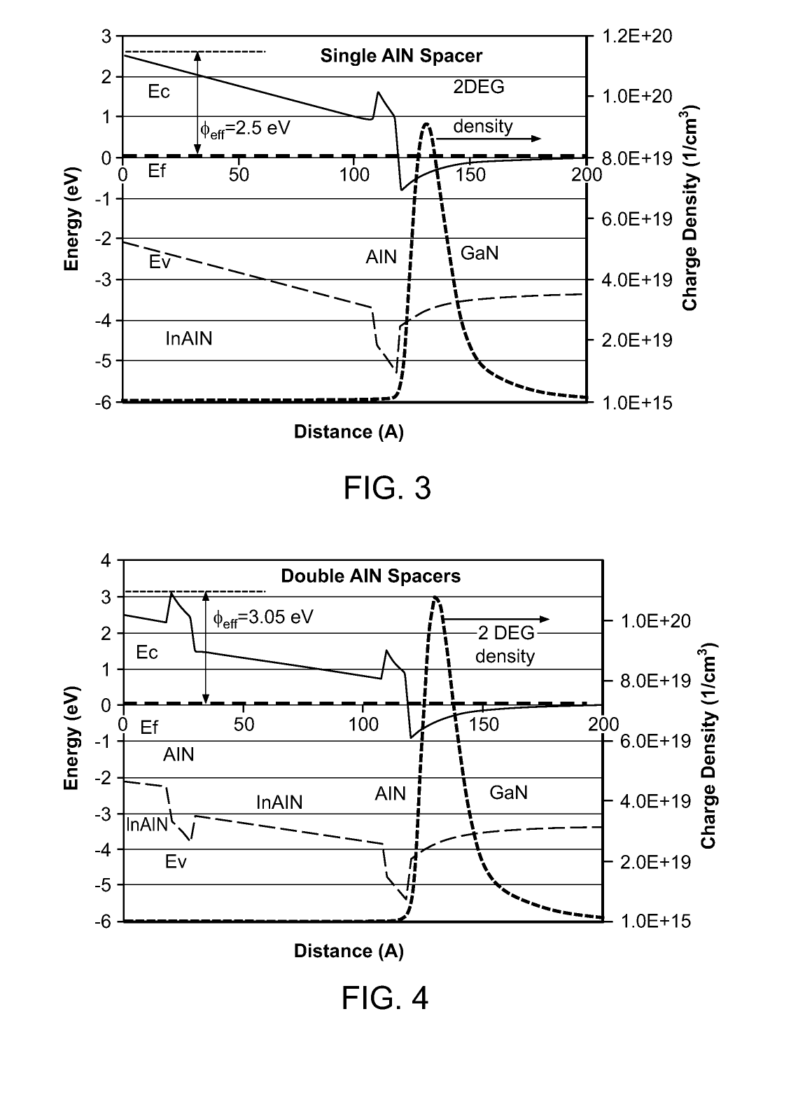

A band diagram is simulated using software to simultaneously solve Poisson and Schrodinger equations in 1 dimension. The bandgap is 6.2 eV for AlN., 3.4 eV for GaN, and 4.6 eV for lattice matched InAlN. The surface barrier height for InAlN is 2.5 eV. As shown in FIGS. 3 and 4, the AlN spacer thickness is 1 nm. The total barrier (AlN+InAlN thickness was fixed at 12 nm. The distribution of 2DEG density is plotted as a function of the depth from the surface.

As can be seen in FIGS. 3 and 4, the effective barrier height φ_{eff} is the barrier height of InAlN, of about 2.5 eV. In the structure with a second AIN spacer, the conduction band offset (Ec) between indium aluminum nitride (InAlN) and aluminum nitride (AlN) causes an effective barrier height of about, 3.05 eV, which is roughly a 22% increase over an equivalent epitaxial structure having only a single AlN spacer. This helps to block electrons flowing from the gate to the channel and hence reduce gate leakage.

### EXAMPLE 2 (PROPHETIC)

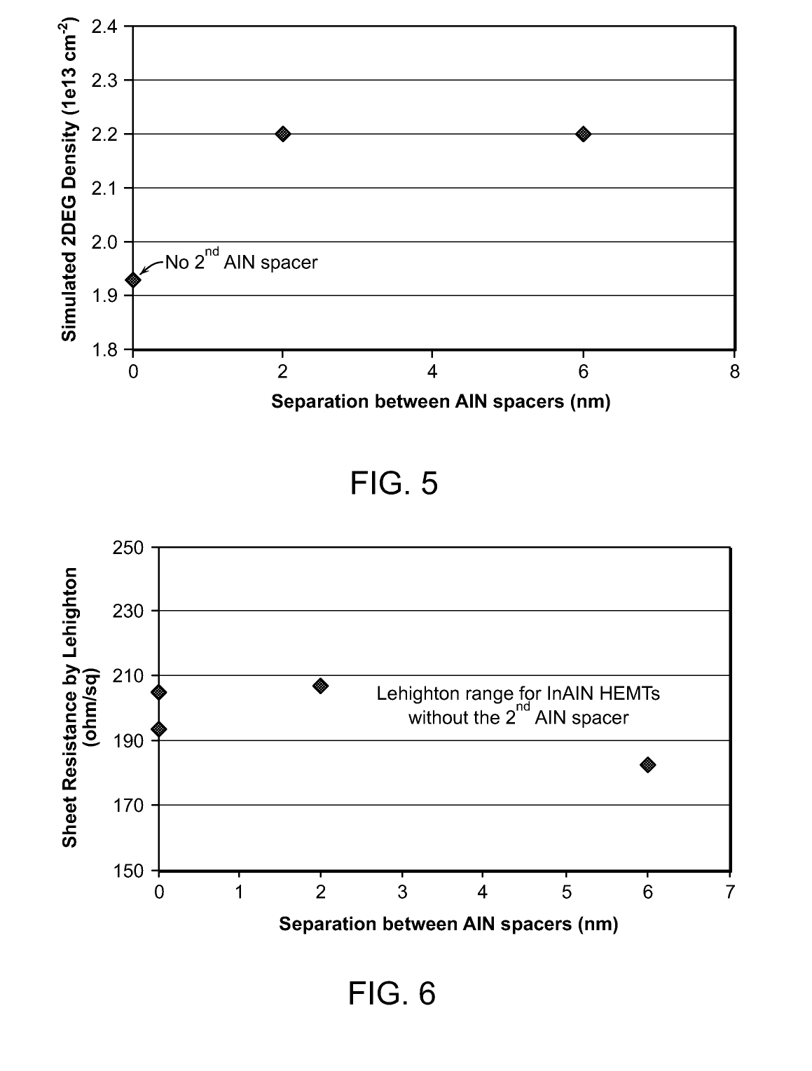

As can be seen in FIG. 5, 2-dimensional electron gas (2DEG) density is simulated with and without a second AIN spacer. The plot shown in FIG. 5 was constructed with total barrier thickness fixed at 11 nm (InAlN and second AlN spacer layer). Changing the AlN spacer position does not significantly change 2DEG density.

As can be seen in FIG. 6, two control samples, having an indium aluminum nitride (InAlN) barrier layer without a second aluminum barrier, were grown in an MOCVD reactor operating at low pressure. The structure consists of a thin gallium nitride (GaN) nucleation layer, 1.9 μm thick carbon-GaN buffer layer, 15 nm thick GaN channel, 1 nm aluminum nitride spacer, and doped 11 nm thick in the indium aluminum nitride (InAlN) barrier. Growth temperature was about 750° C. for the barrier layer 42 and 46 and about 1030° C. for the GaN channel layer 38. Two more samples were grown with the second AlN spacer inserted in the middle of the InAlN barrier. Separation of the two AlN spacers was 2 nm and 6 nm for the two samples. The growth conditions for the second AlN spacer were the same in the control samples.

The two control samples show sheet resistance range between 193 and 200 ohms/sq. The structures with the second aluminum nitrite (AlN) spacer exhibit sheet resistance of 206 and 183 ohms/sq, respectively, which are very close to the control range, indicating there is no degradation in 2 DEG transport properties.

### EXAMPLE 3

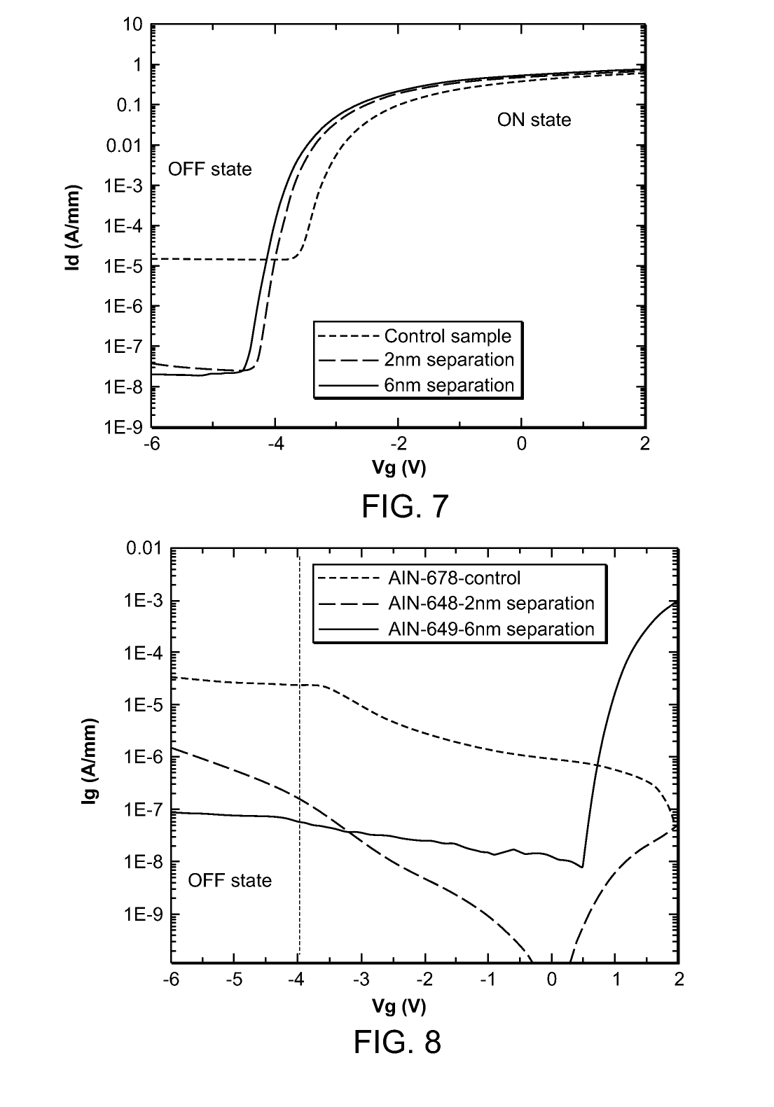

HEMT devices were fabricated using a control sample and two other samples with second AlN spacers. The fabricated gate length was ˜1 μm. The separation between gate and drain was ˜3 μm. The separation between gate and source was ˜1 μm. The source-drain bias was fixed at 6V. The gate bias was swept between −6 and 2V. FIG. 7 shows the plot of the channel current as a function of the gate bias. At off state, the drain-source current in the control sample is ˜3e-5 A/mm, compared to 1.5e-6 A/mm and 9e-8 A/mm in the samples with the second AlN spacer layer. Thus the devices can be turned off more completely at OFF status. The ON/OFF ratio is improved more than two orders of magnitude in the sample with the 6 μm separation between two AlN spacers. FIG. 8 shows the gate leakage current as a function of gate bias. The gate leakage at OFF state is reduced by more than two orders of magnitude.

### Equivalents

While this invention has been particularly shown and described with references to example embodiments thereof, it will be understood by those skilled in the art that various changes in form and details may be made therein without departing from the scope of the invention encompassed by the appended claims.

The relevant teachings of all patents, published patent applications, and publications cited are incorporated herein by reference in their entirety.

What is claimed is:

1. An epitaxial structure, comprising:
a) a substrate;
b) a buffer layer on the substrate;
c) a channel layer over the buffer layer, wherein the channel layer includes a 2-dimensional electron gas;
d) a first spacer layer on the channel layer;
e) a first barrier layer on the first spacer layer;
f) a second spacer layer on the first barrier layer; and
g) a second barrier layer on the second spacer layer;

2. The epitaxial structure of claim 1, wherein the first and second barrier layers are each independently formed of at least one member of the group consisting of aluminum nitride, aluminum gallium nitride, indium aluminum nitride, and indium aluminum gallium nitride.

3. The epitaxial structure of claim 2, wherein the first and second barrier layers each independently consist essentially of In_{y}Ga_{z}Al_{1-y-z}N, where 0.03≦y≦0.3 and 0.01≦z≦0.1.

4. The epitaxial structure of claim 3, wherein the channel layer consists essentially of InₓGa₁₋ₓN, where 0≦x≦1.

5. The epitaxial structure of claim 4, wherein the first spacer layer is formed of a material selected from the group consisting of aluminum nitride, aluminum gallium nitride.

6. The epitaxial structure of claim 5, wherein the second spacer layer is formed of a material selected from the group consisting of aluminum gallium nitride, indium aluminum gallium nitride.

7. The epitaxial structure of claim 6, wherein the average collective thickness of the first and second barrier layers, and the second spacer layer is about 11 nm.

8. The epitaxial structure of claim 7, wherein the first barrier layer has an average thickness of about 8 nm, the second barrier layer has an average thickness of about 2 nm and the second spacer layer has an average thickness of about 1 nm.

9. The epitaxial structure of claim 8, wherein the first spacer layer has an average thickness of about 1 nm.

10. The epitaxial structure of claim 9, wherein the substrate is formed of at least one material selected from the group consisting of silicon carbide (SiC), sapphire (Al₂O₃), silicon (Si), gallium nitride (GaN), and aluminum nitride (AlN).

11. The epitaxial structure of claim 10, further including a back barrier layer between the buffer layer and the channel layer.

12. The epitaxial structure of claim 11, wherein the buffer layer includes at least one material selected from the group consisting of gallium nitride, indium gallium nitride and aluminum gallium nitride.

13. The epitaxial structure of claim 1, wherein the epitaxial structure is a high electron mobility transistor.

14. The epitaxial structure of claim 13, further including:
a) a source terminal in electrical communication with the second barrier layer;
b) a drain terminal in electrical communication with the second barrier layer; and
c) a gate in electrical communication with at least one of the first and second barrier layers and between the source and drain terminals.

15. A method of forming an epitaxial structure, comprising the steps of:
a) forming a buffer layer on a substrate;
b) forming a channel layer on the buffer layer;
c) forming a first spacer layer on the channel layer;
d) forming a first barrier layer on the first spacer layer;
e) forming a second spacer layer on the first barrier layer; and
f) forming a second barrier layer on the second spacer layer whereby a 2-dimensional electron gas region is formed in the channel layer as a result of forming the first and second barrier layers.

16. The method of claim 15, wherein the first and second barrier layer are each independently formed of at least one member of the group consisting of aluminum nitride, aluminum gallium nitride, indium aluminum nitride and indium aluminum gallium nitride.

17. The epitaxial structure of claim 16, wherein the first and second barrier layers each independently consist essentially of In_{y}Ga_{z}Al_{1-y-z}N, where 0.03≦y≦0.3 and 0.01≦z≦0.1.

18. The method of claim 17, wherein the channel layer includes at least one member selected from the group consisting of gallium nitride and indium gallium nitride.

19. The method of claim 18, wherein the first spacer layer is formed of a material selected from the group consisting of aluminum nitride, aluminum gallium nitride.

20. The method of claim 19, wherein the second spacer layer is formed of a material selected from the group consisting of aluminum gallium nitride, indium aluminum gallium nitride.

21. The method of claim 20, wherein the average collective thickness of the first and second barrier layers, and the second spacer layer, is about 11 nm.

22. The method of claim 21, wherein the first barrier layer has an average thickness of about 8 nm, the second barrier layer has an average thickness of about 2 nm and the second spacer layer has an average thickness of about 1 nm.

23. The method of claim 22, wherein the first spacer layer has an average thickness of about 1 nm.

24. The method of claim 23, wherein the substrate is formed of at least one material selected from the group consisting of silicon carbide, sapphire silicon, gallium nitride, and aluminum nitride.

25. The epitaxial structure of claim 24, further including a back barrier layer between the buffer layer and the channel layer.

26. The method of claim 25, wherein the buffer layer includes at least one material selected from the group consisting of gallium nitride.

27. The epitaxial structure of claim 26, wherein the epitaxial structure is a high electron mobility transistor.

28. The method of claim 27, further including the steps of:
a) forming a source terminal in electrical communication with the second barrier layer;
b) forming a drain terminal in electrical communication with the second barrier layer; and
c) forming a gate terminal in electrical communication with at least one of the first and second barrier layers between the source and drain terminals.

29. An epitaxial structure, comprising:
a) a substrate;
b) a buffer layer on the substrate;
c) a channel layer over the buffer layer, wherein the channel layer includes a 2-dimensional electron gas region;
d) a first spacer layer on the channel layer;
e) a first barrier layer on the first spacer layer; and
f) a second spacer layer on the first barrier layer.

30. A method of forming an epitaxial structure, comprising the steps of:
a) forming a substrate;
b) forming a buffer layer on the substrate;
c) forming a channel layer over the buffer layer;
d) forming a first spacer layer on the channel layer;
e) forming a first barrier layer on the first spacer layer; and
f) forming a second spacer layer on the first barrier layer, whereby a 2-dimensional electron gas region is formed in the channel layer as a result of forming the first and second barrier layers.
